(19) United States
(12) Patent Application Publication
(10) Pub. No.: US 2013/0026575 A1
(43) Pub. Date: Jan. 31, 2013

(54) THRESHOLD ADJUSTMENT OF TRANSISTORS BY CONTROLLED S/D UNDERLAP

(71) Applicants: Victor Moroz, Saratoga, CA (US); James D. Sproch, Monte Sereno, CA (US)

(72) Inventors: Victor Moroz, Saratoga, CA (US); James D. Sproch, Monte Sereno, CA (US)

(73) Assignee: SYNOPSYS, INC., Mountain View, CA (US)

(21) Appl. No.: 13/193,320

(22) Filed: Jul. 28, 2011

(51) Int. Cl. H01L 27/12; H01L 21/336

(52) U.S. Cl. 257/348; 438/302; 257/E27.112; 257/E21.409

(57) ABSTRACT

Roughly described, an integrated circuit device has formed on a substrate a plurality of transistors including a first subset of at least one transistor and a second subset of at least one transistor, wherein all of the transistors in the first subset have one underlap distance and all of the transistors in the second subset have a different underlap distance. The transistors in the first and second subsets preferably have different threshold voltages, and preferably realize different points on the high performance/low power tradeoff.

### BACKGROUND

The invention relates to integrated circuit devices, and more particularly to devices having transistors with different threshold voltages.

Planar MOSFET devices generally include source and drain diffusion regions on longitudinally opposite sides of a channel region. A gate stack including a gate conductor over a thin dielectric material overlies the channel. As MOSFET geometries shrink, the leakage current (I_{off}, the drain current that flows at high drain bias and zero gate bias) increases due to a variety of effects. Transistors with high I_{off} current consume significant amounts of power, and are therefore detrimental for circuits requiring low power consumption. The I_{off} current can be reduced by increasing the threshold voltage V_{T} of the transistor, but this also reduces the transistor ‘on’ current Iₒₙ (the drain current at high drain and gate bias), as well as the transistor switching speed. A tradeoff therefore exists between high performance transistors and low power transistors. For some applications, this tradeoff is optimized for the particular application, and all the transistors on the device are fabricated according to the optimized position. For other applications, the tradeoff is avoided by implementing low V_{T} transistors for only those parts of the circuit requiring higher performance, such as transistors in a critical path. Higher V_{T} transistors are implemented for the remainder of the circuit.

For planar MOSFETs, a primary mechanism for implementing a desired V_{T} has been adjustment of the doping concentration in the channel region of the transistor. Halo implants can also be adjusted. However, as channel dimensions shrink, small random fluctuations in channel dopant levels are causing significant random and uncontrolled variations in transistor threshold voltages. Newer fabrication processes are avoiding any doping of the channel region, replacing planar MOSFETs with either FinFETs or ETSOI (Extremely Thin Silicon-On-Insulator) MOSFETs. These transistor types both have fully depleted undoped channels, and no halos. On the positive side, the undoped channel improves carrier mobility and eliminates random dopant fluctuations. On the negative side, it removes the primary approach for adjusting threshold voltage—adjusting the doping level in the channel region.

Other approaches exist for adjusting transistor threshold voltage. In one approach, known as work function engineering, different materials or material doping levels are provided in place of the conventional gate stack materials. One set of materials or doping levels are provided for high performance transistors, and a different set of materials or doping levels are provided for low power transistors. In another approach, for SOI devices, the thickness of the silicon layer is adjusted. One thickness is used for high performance transistors, and a different thickness is used for low power transistors. In yet another approach, the gate dielectric thickness and/or material are adjusted, resulting in a desired effective dielectric thickness. One effective thickness is used for high performance transistors, and a different effective thickness is used for low power transistors.

While all of these approaches can be used, they all have drawbacks. For work function engineering, for example, the use of selected gate stack materials offers only individual discrete points in the high performance/low power tradeoff, thereby often precluding optimal choice of threshold voltage for each type of transistor. And the use of different materials can be expensive, and can be prohibitively expensive if three or more different transistor threshold voltages are desired on a particular chip. Similarly, a change in the thickness of the effective gate dielectric material, can degrade performance.

It would be desirable to find a different mechanism for implementing transistors with different threshold voltages on a single integrated circuit device.

### SUMMARY

An opportunity therefore arises to create robust solutions to the problem of implementing transistors with different threshold voltages on a single integrated circuit device. The problem is especially acute for processes having fully depleted channels, where selective channel doping is unavailable. Better products, with higher overall performance and lower overall power dissipation, may result.

Roughly described, the invention involves an integrated circuit device having formed on a substrate a plurality of transistors of a first conductivity type, including a first subset of at least one transistor and a second subset of at least one transistor, wherein all of the transistors in the first subset have one source/drain underlap distance and all of the transistors in the second subset have a different source/drain underlap distance. The transistors in the first and second subsets preferably have different threshold voltages, and preferably realize different points on the high performance/low power tradeoff.

The above summary is provided in order to provide a basic understanding of some aspects of the invention. This summary is not intended to identify key or critical elements of the invention or to delineate the scope of the invention. Its sole purpose is to present some concepts of the invention in a simplified form as a prelude to the more detailed description that is presented later. Particular aspects of the invention are described in the claims, specification and drawings.

### BRIEF DESCRIPTION OF THE DRAWINGS

The invention will be described with respect to specific embodiments thereof, and reference will be made to the drawings, in which:

FIG. 1 is a simplified diagram of a conventional planar MOSFET transistor.

FIG. 2 illustrates a typical ETSOI transistor.

FIG. 3 is a plot illustrating relationships between threshold voltage and leakage current, and S/D underlap distance for a transistor with a fully depleted channel, such as an ETSOI or FinFET.

FIG. 4 is a plot illustrating a relationship between effective ‘on’ current I_{eff} and S/D underlap distance.

FIG. 4A is a plot illustrating a relationship between I_{off} and I_{eff}.

FIG. 5 illustrates a substrate having transistors with three different underlap distances.

FIGS. 6A-J (collectively FIG. 6) illustrate pertinent steps of an ETSOI fabrication process according to the invention.

FIGS. 7A, 7B, 8A and 8B illustrate pertinent steps of a FinFET fabrication process according to the invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

FIG. 1 is a simplified diagram of a conventional planar MOSFET transistor. It includes source and drain diffusion regions 110, 112 separated longitudinally by a channel region 114. Superposing the channel region 114 is a gate stack 116. As used herein, the “longitudinal” direction of a transistor is the direction of current flow from one current path terminal (source or drain) to the other when the transistor is turned on. The longitudinal direction in FIG. 1 is indicated by the arrow 118. The “transverse” direction is perpendicular to the longitudinal direction, and perpendicular to the direction of current flow, and perpendicular to the page on which FIG. 1 is printed. Both the longitudinal and transverse directions of the transistor are considered to be “lateral” directions, meaning a direction that is parallel to the surface. Other “lateral” directions include those (not shown) which are parallel to the surface but intersect both the transverse and longitudinal directions at angles. The “vertical” direction is normal to the surface of the channel and therefore perpendicular to all possible lateral directions. The “length” of a structure in the layout is its length in the longitudinal direction, and its “width” is its width in the transverse direction. The transistor of FIG. 1 can be of either conductivity type (N-channel or P-channel).

It can be seen from FIG. 1 that in a planar MOSFET integrated circuit, the gate typically slightly overlaps both the source and drain diffusions longitudinally. This positive overlap is typically the same on both the source and drain sides of the gate, and is typically the same for all transistors of a given conductivity type on the device. The S/D overlap is typically slightly different for transistors of opposite conductivity types.

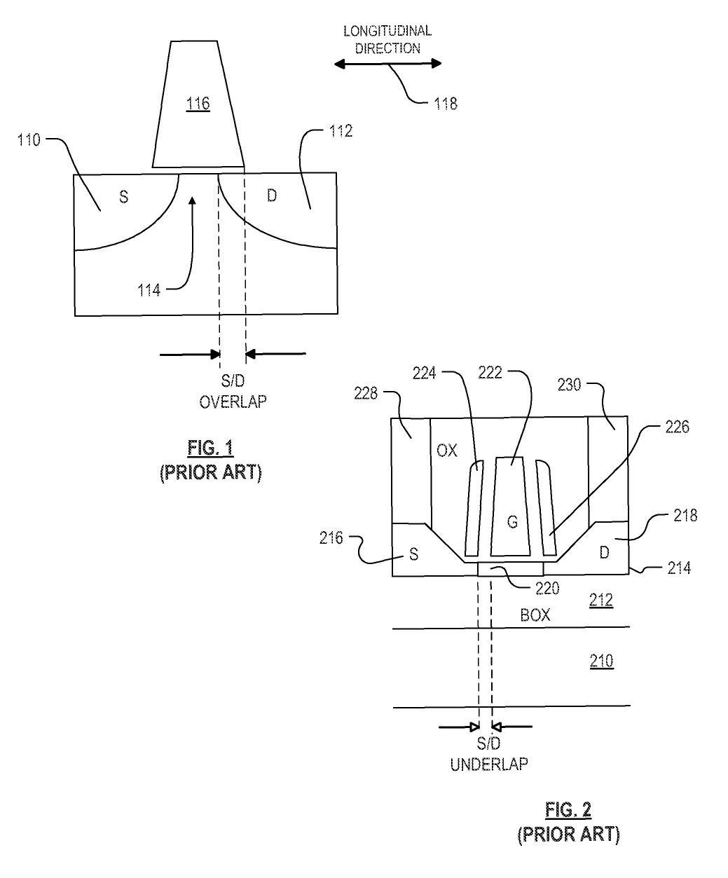

FIG. 2 illustrates a typical ETSOI transistor. It comprises a substrate material 210, superposed by an insulator (in this case an oxide) 212, superposed in turn by a silicon layer 214. As used herein, layers which are termed “above” or “below” other layers, can in various embodiments be separated from such other layers by one or more intervening layers. If no intervening layer is intended, then the terms “immediately above” or “immediately below” are used herein. The same interpretation is intended for layers being described as “superposing”, “underlying” or “over” another layer. In addition, as used herein, the term “layer” can include sublayers, which themselves can be considered herein to constitute layers. Also as used herein, a “layer” may be patterned or unpatterned. By itself the term does not imply either condition. In the structure of FIG. 2, the transistor has raised source and drain regions 216 and 218, respectively, separated longitudinally by a channel region 220. The channel region 220 is fully depleted and undoped. Metal contacts 228 and 230 connect to the source and drain regions 216, 218, respectively. Superposing the channel region is a gate stack which includes a gate conductor 222, and spacers 224 and 226 on respectively the source and drain sides of the gate 222. The source and drain regions are formed by a self-aligned process, in which the gate stack, including the spacers 224 and 226, are used as a mask. The source and drain regions may for example be formed by selective epitaxy with in-situ doping. The longitudinal edges of these regions adjacent the gate stacks are defined by the longitudinal edges of the spacers 224 and 226, but the dopants also diffuse under the spacers toward the channel region somewhat by a distance that depends on various process parameters such as the epitaxial growth time and thermal budget.

The longitudinal boundaries of channel 220 are defined by the positions of the adjacent longitudinal boundaries of the source and drain regions. Because of the nature of the diffusion in silicon, these interfaces are gradual rather than abrupt. Therefore, for purposes of the present discussion, the location of the interface is defined herein as the longitudinal position at which the dopant concentration falls to 10¹⁹ atoms per cubic centimeter. The dopant concentration at a particular longitudinal position is considered to be an average at that longitudinal position, taken transversely across the channel width.

It can be seen that there is a small spacing between the longitudinal position of the edge of the channel region 220 and the longitudinal position of the edge of the gate 222. This spacing, called the S/D underlap, is the same on both the source and drain sides in a conventional transistor. As used herein, the “underlap distance” is the distance by which the channel extends longitudinally beyond the edge of the gate. “Overlap distance”, as the term is used herein, is the distance by which the channel terminates short of the edge of the gate (see FIG. 1). The two terms are used herein in a complementary manner, meaning a negative overlap is a positive underlap and vice-versa. “S/D” underlap or overlap refers to the underlap or overlap on either the source or drain side of the gate or both. “S underlap” or “S overlap” refers specifically to the underlap or overlap on the source side of the gate, and “D underlap” or “D overlap” refers specifically to the underlap or overlap on the drain side of the gate.

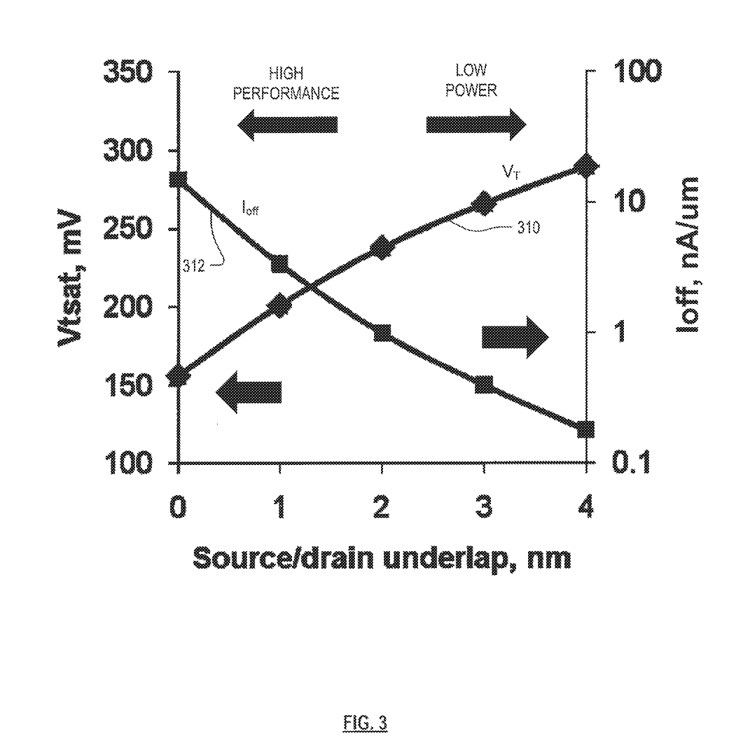

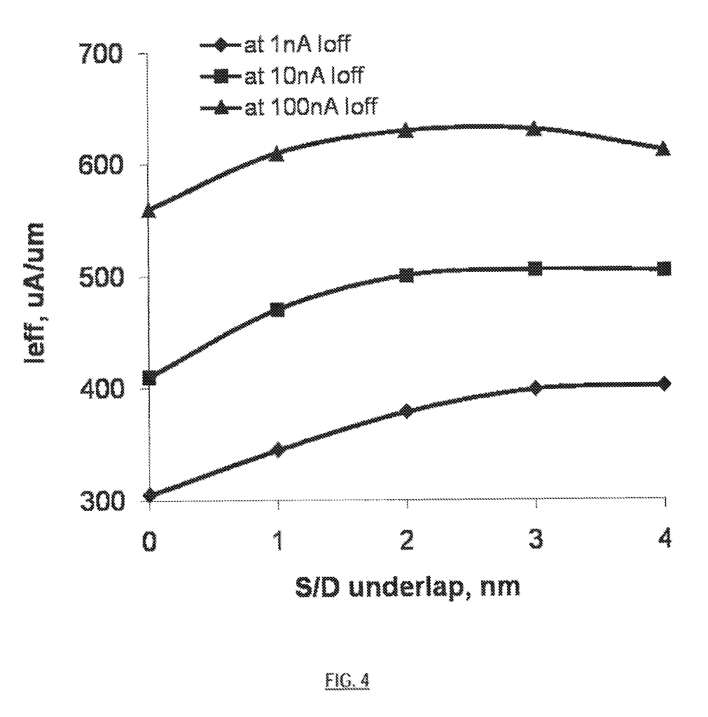

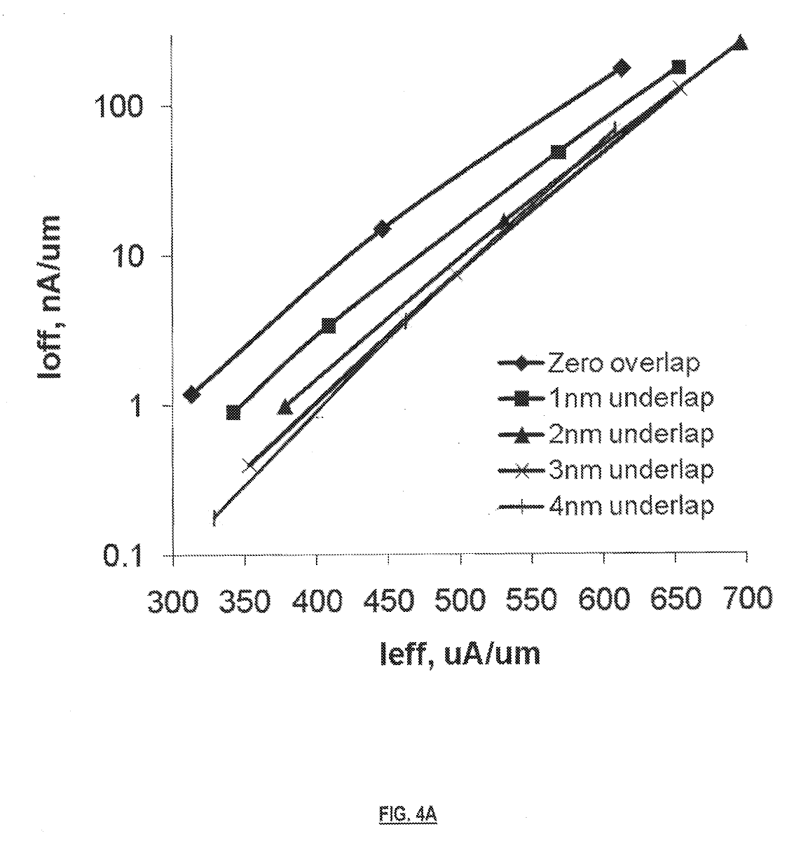

FIG. 3 is a plot illustrating how both the threshold voltage and the leakage current vary in dependence upon the S/D underlap distance of a fully depleted transistor. Curve 310 represents the threshold voltage V_{T} and curve 312 represents the leakage current I_{off}. It can be seen that as the underlap distance increases, V_{T} increases and I_{off} decreases. FIG. 4 is a plot illustrating how the effective ‘on’ current I_{eff} varies as a function of the S/D underlap distance of a transistor, for three specific values of I_{off}. I_{eff} is a measure of the average ‘on’ current that the transistor is likely to experience in operation, which correlates with transistor performance as that term is used herein. For purposes of the present discussion I_{eff} is given by

I_{eff}=0.5[(I_{d}(V_{gs}=V_{dd},V_{ds}=V_{dd}/2)+I_{d}(V_{gs}=V_{dd}/2,V_{ds}=V_{dd})]

where:

I_{d} is the drain current

V_{gs} is the gate-to-source voltage

V_{dd} is the supply voltage

V_{ds} is the drain-to-source voltage.

It can be seen from FIG. 4 that I_{eff} does not degrade with increasing S/D underlap distance, except at high I_{off} and underlap distances greater than about 3 nm.

FIG. 4A, is a plot illustrating how I_{off} varies with I_{eff} for several individual underlap distances. It can be seen that the I_{eff}-I_{off} trade-off curve is nearly insensitive to underlap distance, especially at underlap distances in the range of 2-4 nm.

FIGS. 3, 4 and 4A together illustrate that different points on the tradeoff between high performance and low power can be selected for a particular transistor by selecting its S/D underlap distance. These distances can be formed independently for each transistor if desired, or preferably, two or three different individual choices can be made available in a cell library for use in a particular design. For example, a cell library can contain one set of high performance cells or transistors, and another set of low power cells or transistors. The high performance transistors have a small S/D underlap, for example in the range of 1-2 nm, and have a lower V_{T}, and a higher I_{off} and I_{eff}; whereas the low power transistors have a larger S/D underlap, for example in the range of 3-4 nm, and have a higher V_{T}, and a lower I_{off} and I_{eff}. As another example, a cell library can contain three sets of cells or transistors: high performance, normal and low power. The high performance transistors have a small S/D underlap, for example in the range of 1-2 nm, and have a low V_{T}. The normal transistors have a medium S/D underlap, for example in the range of 2-3 nm, and have a medium V_{T}. The low power transistors have a large S/D underlap, for example in the range of 3-4 nm, and have a higher V_{T}.

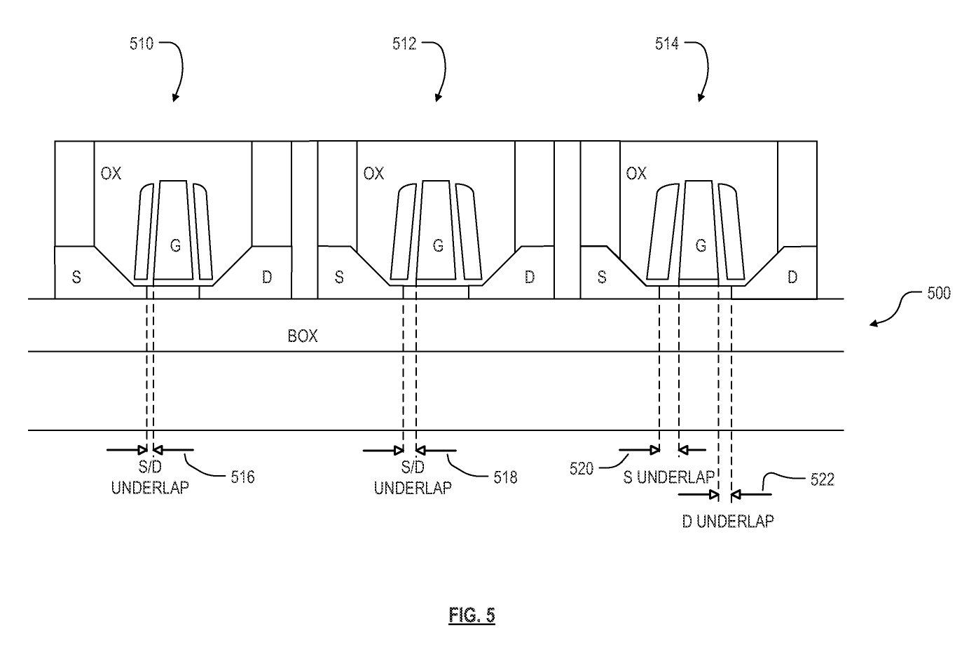

FIG. 5 illustrates transistors with three different underlap distances on a single integrated circuit chip 500. Transistor 510 is designed for high-performance at the expense of low power. It has a very narrow S/D underlap distance, as indicated by indicator 516. For example, the S/D underlap distance 516 may be on the order of 0-2 nm. Transistor 512 has both medium performance and medium power dissipation. It has a medium S/D underlap distance, as indicated by indicator 518. Transistor 514 is designed for low power at the expense of high performance, and has a large S/D underlap distance, at least on the source side, as indicated by indicator 520. Transistor 514 in FIG. 5 serves to illustrate the further point that the underlap distance on the source side is much more significant than that on the drain side in choosing the point on the high-performance/low power trade-off. The underlap distance on the drain side can vary widely, without significantly affecting the point on the trade-off that is established by the underlap distance on the source side. Thus in FIG. 5, whereas the drain underlap distance in transistors 510 and 512 each equal their corresponding source underlap distances, the drain underlap distance 522 in transistor 514 is different from the source underlap distance 520 of transistor 514. Note that a differential between the source and drain underlap distances may be difficult to achieve in a fabrication process, and is not preferred.

As used herein, the substrate in FIG. 5 may be said to “carry” all of the components of the three transistors 510, 512 and 514. The term “carrying” is not intended herein to distinguish between substances disposed in the substrate body itself, or disposed in or on an overlying layer. Transistors can be fabricated with more than one underlap distance on a single chip, by a variety of different methods. One preferred method takes advantage of the observation that the underlap distance depends to a large degree on the thickness of the spacers on the two longitudinal sides of the gate electrode. Thus during the formation of the gate stacks, some transistors can be formed with narrow spacers whereas others can be formed with wider spacers, and in a process that offers three different points on the trade-off, still other transistors can be formed with still wider spacers. Since the distance by which the source and drain dopants diffuse inwardly from the longitudinally outer edges of the spacers is roughly constant for a given in-situ doping environment, the width of the spacers largely determines how far the dopants diffuse toward the edge of the gate electrode.

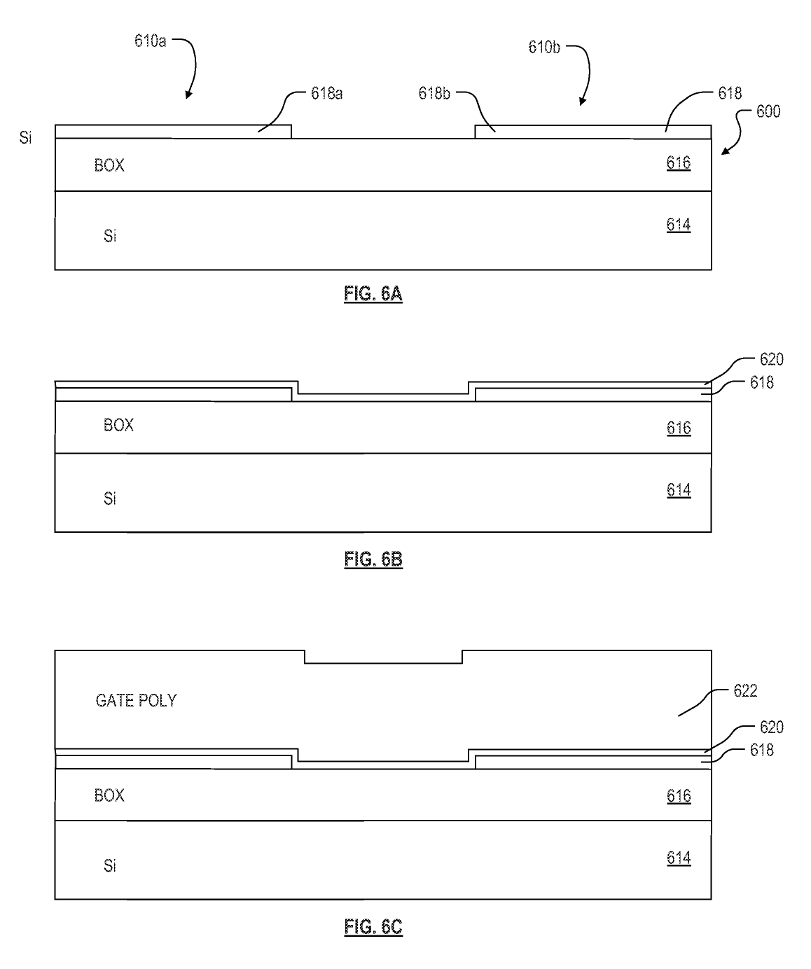

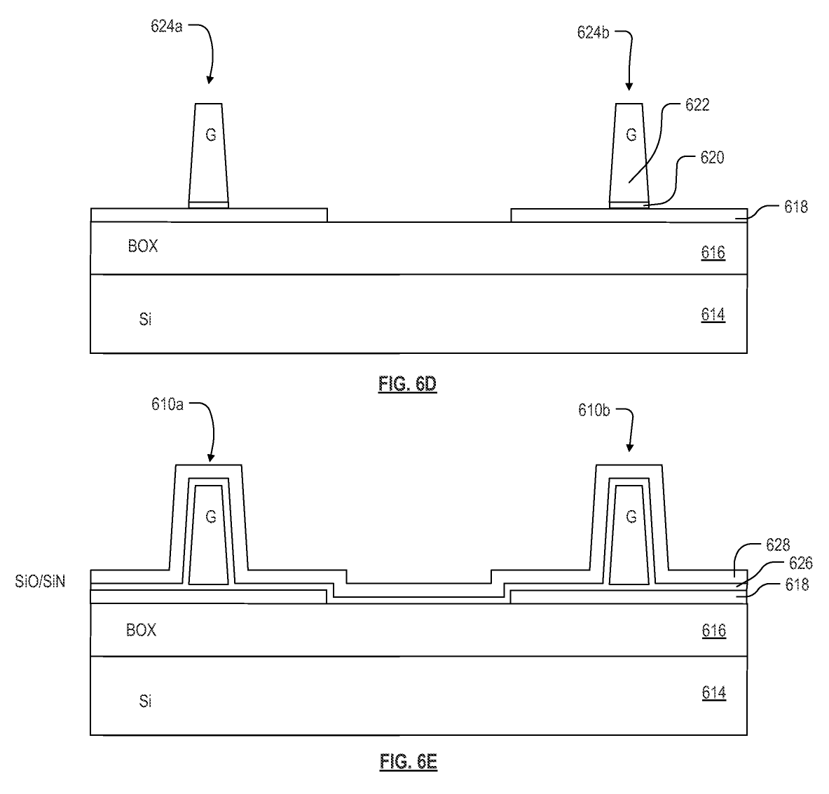

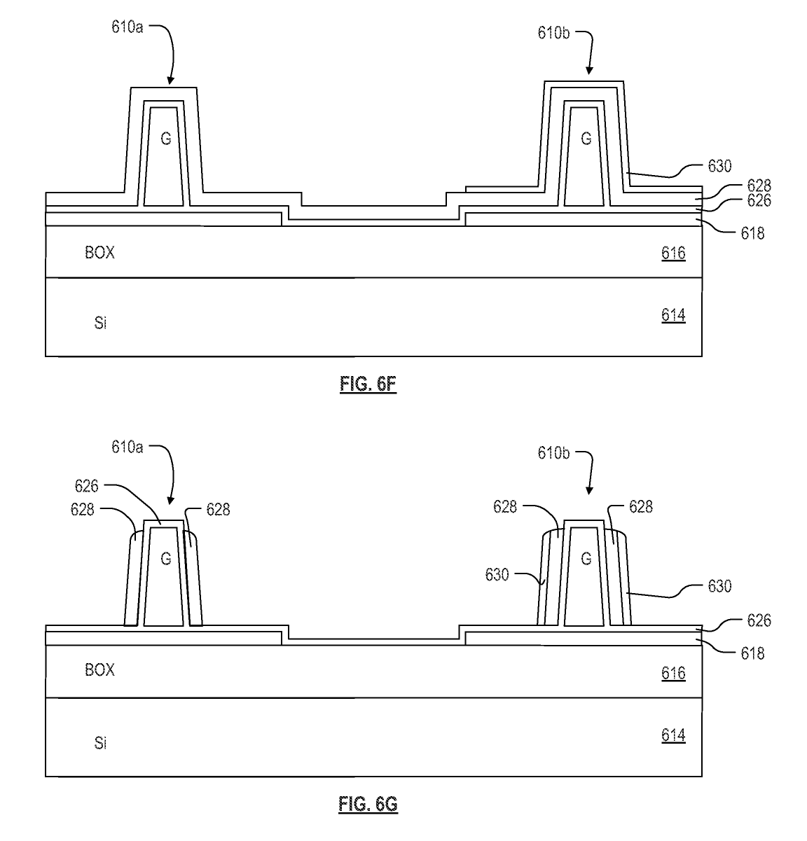

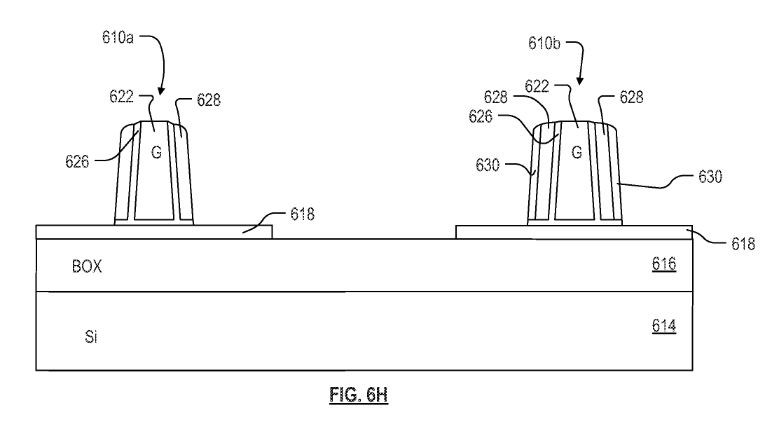

FIGS. 6A-J (collectively FIG. 6) illustrate pertinent steps of a fabrication process that can be used to form transistors having two different S/D underlap distances on a single substrate. Transistor 610a will be a high-performance transistor, whereas transistor 610b will be a low-power transistor. In FIG. 6A, there is shown an SOI (silicon on insulator) wafer 600 comprising a bulk silicon substrate 614 underlying a buried oxide layer 616. The silicon layer 618 on the top has already been patterned to individuate the transistors. Thus two silicon regions 618a and 618b, for transistors 610a and 610b respectively, are shown. The silicon regions 618a and 618b are undoped.

In FIG. 6B, a thin layer of gate oxide or other gate dielectric material 620 is formed over the silicon layer 618, and in FIG. 6C, a layer of gate polysilicon or other gate electrode material 622 is formed over the gate dielectric layer 620. The gate dielectric layer 620 can be (but is not limited to) SiO₂, SiON, or a metal oxide such as (but not limited to) HfO₂, HfSiOₓ, HfSiOₓN_{y}, Ta₂O₅, TiO₂, Al₂O₃, Y₂O₃ and La₂O₅. In some embodiments, the metal oxide creates a high-k layer. The material comprising the gate electrode 622 depends on the choice of the gate dielectric layer 620. For example, in the case of Si-based oxides, polysilicon can be used. In the case of metal oxides, a metal can be used such as (but not limited to) TiN, Ta, TaN, TaCN, TaSiN, TaSi, AN, W and Mo. The gate dielectric layer 620 and gate electrode 622 can be deposited using any conventional deposition process such metal-organic chemical vapor deposition (“MOCVD”) or atomic-layer deposition (“ALD”) and physical vapor deposition (“PVD”), as appropriate for the material being deposited. Note that in an alternative embodiment, used in a gate-last high-k metal gate (HKMG) process, the gate stack can be disposable and will be replaced at a later step.

In FIG. 6D, the combination of gate electrode layer 622 and gate dielectric layer 620 is patterned photo-lithographically to form partial gate stacks 624a and 624b (collectively 624) for the two transistors 610a and 610b, respectively. In one embodiment the gate poly layer 622 is patterned first using a directional etch method, and the gate dielectric layer 620 is patterned next. In another embodiment, both layers 622 and 620 are patterned in a single step. RIE can be used in either embodiment.

In FIG. 6E, a layer of oxide 626 is deposited conformally over the silicon layer 618 and the partial gate stacks 624. A further layer 628 of silicon nitride is deposited conformally over the oxide layer 626. At this point, the sidewall spacers on the gates of both transistors 610a and 610b have the same thickness. Note that other materials aside from oxide and SiN can be used as spacer material in a different embodiment.

In FIG. 6F, an additional layer of spacer material 630, such as another layer of silicon nitride, is deposited only over the low power transistor 610b. Selective deposition of layer 630 can be performed by applying photoresist over the entire wafer, and photo-lithographically opening windows to expose only those transistors (like 610b) that are to be low power transistors. The layer 630 of silicon nitride is then deposited only where the resist window is open.

In FIG. 6G, the silicon nitride layers 628 and 630 are directionally etched until the oxide layer 626 is reached. This leaves oxide and silicon nitride sidewalls 626 and 628 on the gate for transistor 610a, and oxide and silicon nitride sidewalls 626, 628 and 630 on the gate for transistor 610b. It can be seen that the sidewalls for transistor 610b are wider than those for transistor 610a. In FIG. 6H, the oxide layer 626 is removed by a wet etch, for example using HF or an HF-vapor based chemical. The silicon layer 618 on either side of the transistor gates is now exposed.

In FIG. 6I, the raised source and drain regions 632a and 632b for transistors 610a and 610b, respectively, are grown, for example by selective silicon or SiGe epitaxy on the exposed silicon layer 618, with in-situ doping of the source and drain regions 632a and 632b (collectively 632). This step is performed separately for N- and P-channel transistors. For example, by mixing dilute phosphine into the growth gasses, N type source/drain regions will be produced. Likewise, the incorporation of diborane during growth creates P type source/drain regions. Note that whereas the raised source and drain regions 632 in FIG. 6I have 55-degree facets, other embodiments using different mechanisms to grow the source and drain regions need not produce such facets.

It can be seen in FIG. 6I that the source and drain regions grow only in the exposed regions of silicon layer 618, which extends longitudinally away from the gate stacks, beginning from the edges of the sidewall spacers. It can also be seen that the dopants diffuse inwardly under the sidewall spacers, by roughly the same longitudinal distance for both transistors 610a and 610b. Thus since the sidewall spacers formed by layers 626, 628 and 630 are wider for transistor 610b than the spacers formed by layers 626 and 628 for transistor 610a, the length of the channel region below the gate stack will be longer for transistor 610b than for transistor 610a. This results in a larger S/D underlap distance 634b for transistor 610b than the S/D underlap distance 634a for transistor 610a. As a result, transistor 610b will have lower power dissipation than transistor 610a, but transistor 610a will have better performance than transistor 610b.

Transistors realizing different points on the speed/power tradeoff through the use of different underlap distances on a single substrate do not necessarily cost significantly more to form than transistors having only one optimized speed/power position because the formation of the second spacer thickness 630 is an inexpensive step. The technique also is less expensive than work function engineering, and works for both gate-first and gate-last HKMG (high-K metal gate technology). Nor does the technique degrade performance. The technique can also be used to design different cell libraries for different points on the speed/power tradeoff.

In FIG. 6J, oxides 636 are formed over all the structures. Vias 638 are opened for the contacts and filled with metal. Other process steps may be performed now as well, in order to finish the wafer or chip. In some embodiments, after formation of the source and drain regions 632, the gate electrode material 622 and/or the gate dielectric material 626 may be removed and replaced with other preferred materials. Further in some embodiments, after formation of the source and drain regions 632, the spacer materials 626, 628 and 630, may be removed and optionally replaced with other preferred materials. Many other variations will be apparent to the reader. All these subsequent steps are understood by the reader and their details are not important for an understanding of the present invention.

Note that selection of underlap distance also can be used in combination with other mechanisms to establish a desired point on the high performance/low power tradeoff. For example, whereas the channel regions in FIG. 6 are undoped, in another embodiment they can be doped, and can be doped differentially depending on the desired point in the tradeoff. As another example, selection of underlap distances does not preclude also using work function engineering, selective silicon layer thickness, and selective gate dielectric thickness, or selective gate dielectric materials.

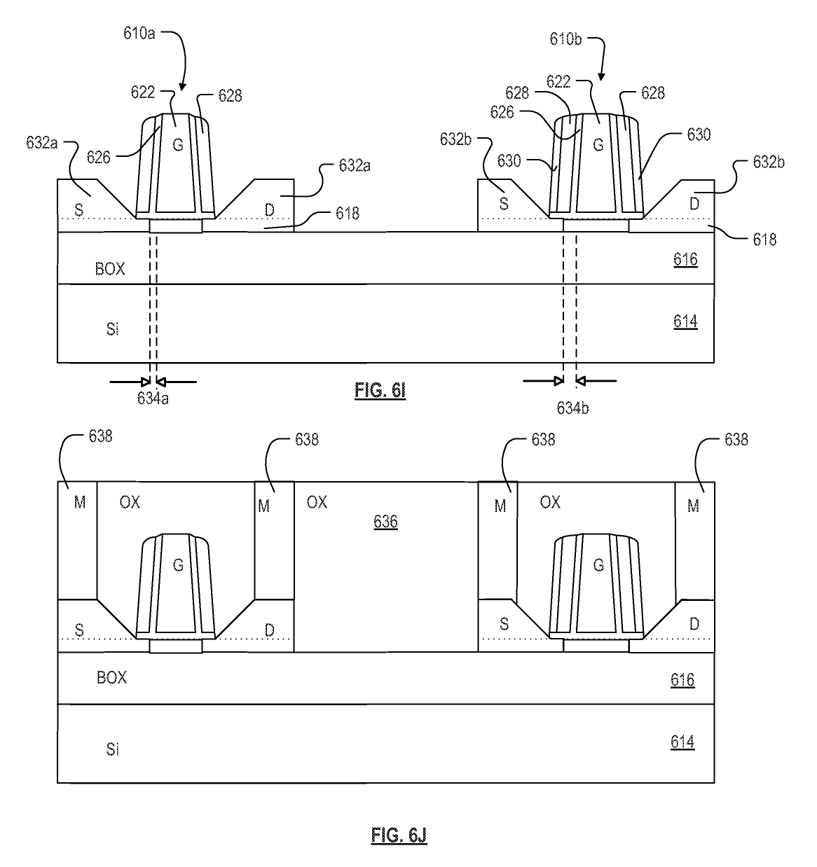

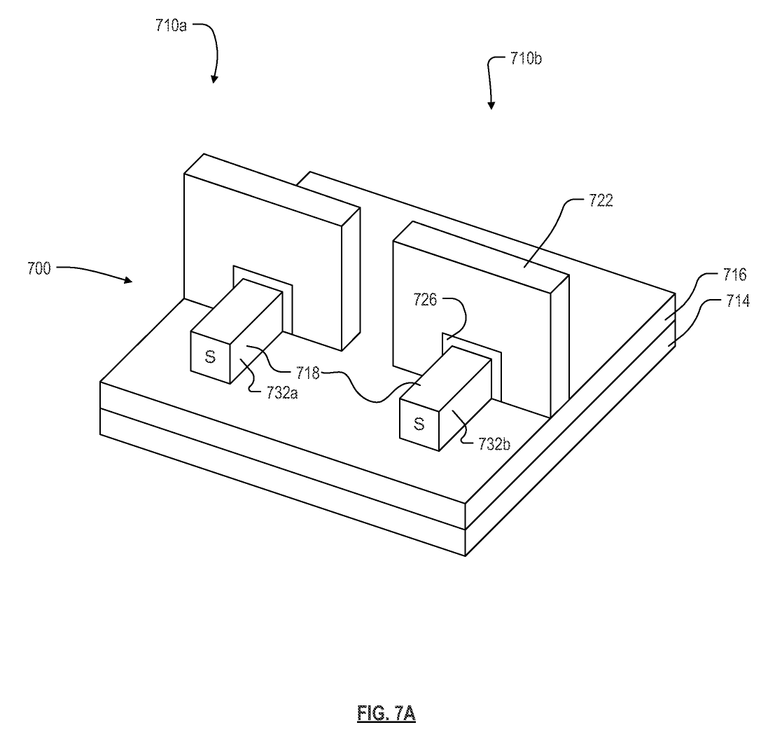

FIGS. 7A-7B (collectively FIG. 7) illustrate in perspective view an embodiment of the invention as used with FinFET transistors. This embodiment is equally representative of dual-gate and triple-gate MOSFETs. In FIG. 7A, an SOI wafer 700 includes two partially completed transistors 710a and 710b. A bulk silicon substrate 714 underlies a buried oxide layer 716, and the undoped silicon layer 718 above them has already been patterned with separate source and drain regions for each of the two transistors. (In another embodiment, not shown, the buried oxide layer 716 can be omitted.) In the drawing, only the source regions 732a and 732b are visible, the drain regions being hidden behind the gate structures. Also, the wider contact portions of the source and drain regions are omitted from the drawing for clarity of illustration. A gate dielectric layer 726 overlies and wraps around the silicon portions 718 for each transistor, and the gate electrodes 722 overlie and wrap around the gate dielectrics 726 for each transistor. In FIG. 7B, spacer material 728 has been formed on the source and drain sides of each of the transistors 710a and 710b. In addition, further spacer material 730 has been formed on the source and drain sides of only transistor 710b, resulting in a thicker overall spacer on transistor 710b than on transistor 710a. Raised source and drain regions are then formed for example by selective epitaxy as previously described, with in-situ doping of the source and drain regions.

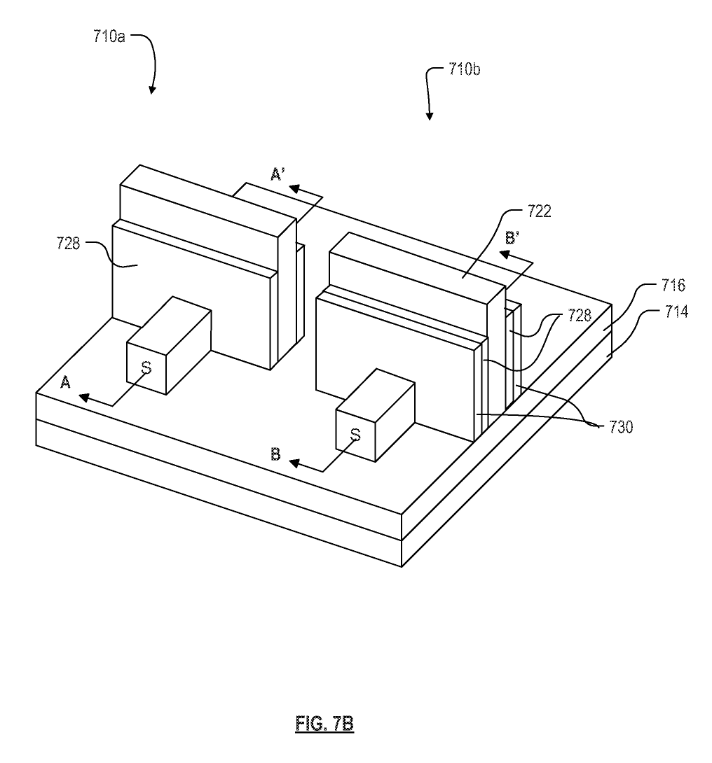

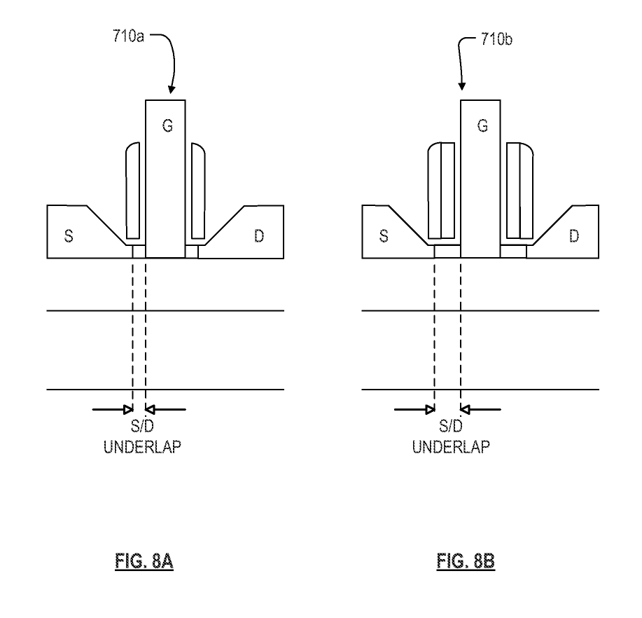

FIGS. 8A and 8B (collectively FIG. 8) illustrate transistors 710a and 710b in a different view. Specifically, FIG. 8A is a cross-sectional view of transistor 710a (FIG. 7B) after formation of the source and drain regions, taken at sight lines A-A′. Similarly, FIG. 8B is a cross-sectional view of transistor 710b after formation of the source and drain regions, taken at sight lines B-B′. Though the two transistors are shown in separate drawing figures for convenience of illustration, they are on a single chip as shown in FIG. 7B. It can be seen that, similarly to transistors 610a and 610b, transistor 710a has a smaller S/D underlap distance than does transistor 710b. Because of this, transistor 710a will be a high-performance transistor, whereas transistor 710b will be a low-power transistor. The different S/D underlap distances arose because the spacers 728 on transistor 710a are narrower than the combined thickness of spacers 728 and 730 on transistor 710b.

Other process steps are subsequently performed on transistors 710a and 710b in order to finish the wafer or chip. These subsequent steps are understood by the reader and their details are not important to an understanding of the present invention. All variations mentioned with respect to the FIG. 6 embodiment apply to the FIG. 7 embodiment as well. In addition, as shown correspondingly in FIG. 5, transistors having three or more different S/D underlap distances can be fabricated by using a corresponding number of different spacer thicknesses.

The embodiments of FIGS. 6 and 7 both implement aspects of the invention using one application of spacer material to all transistors, followed by a second application of spacer material to only those transistors which are to have a larger S/D underlap distance. In another embodiment, the first and second spacer thicknesses can be achieved by selectively applying spacer material to only those transistors which are to have the first thickness, then selectively applying spacer material of a different thickness to only those transistors which are to have the second thickness. The source and drain regions for all transistors are formed thereafter, as they are in FIGS. 6 and 7. Many other methods will be apparent to the reader for forming gate stacks with differing spacer thicknesses on a single substrate.

In addition, whereas the embodiments of FIGS. 6 and 7 both implement aspects of the invention using two or more thicknesses of spacer material, there are other ways to form transistors with different S/D underlap distances using only one thickness of spacer material. In one embodiment, after all the spacers are formed to a single thickness, two or more different dopants having different rates of diffusion in silicon are used to dope the source and drain regions for each transistor conductivity type. For example, the source and drain regions of N-channel transistors which are to have a smaller S/D underlap can be doped with phosphorus, whereas the source and drain regions of N-channel transistors which are to have a larger S/D underlap can be doped with arsenic. Similarly, the source and drain regions of P-channel transistors which are to have a smaller S/D underlap can be doped with boron, whereas the source and drain regions of P-channel transistors which are to have a larger S/D underlap can be doped with indium. Since P and B diffuse in silicon more quickly than As and In, a smaller S/D underlap will result in the transistors doped with P and B.

In another embodiment, after all the spacers are formed to a single thickness, different tilt angles can be used to implant dopant atoms into the source and drain regions of transistors which are to have different S/D underlap distances. For example, transistors which are to have a larger S/D underlap distance can be doped using an ion implant tilt angle which is very close to vertical, whereas transistors which are to have a smaller S/D underlap distance can be doped using an ion implant tilt angle which is at a greater angle to the vertical, so as to implant ions directly below the spacer.

In yet another embodiment, the different S/D underlap distances can be achieved using different anneal steps. After all the spacers are formed to a single thickness, the source and drain regions of only a first subset of the transistors, are doped. The wafer is then annealed, which causes dopant atoms to diffuse by some distance longitudinally under the spacers for the first subset of transistors. Then the source and drain regions of only a second subset of the transistors, are doped. (Alternatively, all transistors can be doped in this second step, resulting in a second doping of the transistors of the first subset.) The wafer is then annealed a second time, which causes dopant atoms to diffuse by some distance longitudinally under the spacers for the second subset of transistors. But this second anneal also causes the dopant atoms in the first subset of transistors to diffuse further under the spacers of those transistors, resulting in a smaller S/D underlap distance than will result in the second subset of transistors.

Many other methods for providing transistors with selective S/D underlap distances will be apparent. In addition, it will be apparent that more than one of the above methods can be combined.

The applicant hereby discloses in isolation each individual feature described herein and any combination of two or more such features, to the extent that such features or combinations are capable of being carried out based on the present specification as a whole in light of the common general knowledge of a person skilled in the art, irrespective of whether such features or combinations of features solve any problems disclosed herein, and without limitation to the scope of the claims. The applicant indicates that aspects of the present invention may consist of any such feature or combination of features. In view of the foregoing description it will be evident to a person skilled in the art that various modifications may be made within the scope of the invention.

The foregoing description of preferred embodiments of the present invention has been provided for the purposes of illustration and description. It is not intended to be exhaustive or to limit the invention to the precise forms disclosed. Obviously, many modifications and variations will be apparent to practitioners skilled in this art. For example, though the embodiments described above illustrate transistors with undoped channels, it will be appreciated that aspects of the invention also apply to transistors with doped channels. Nor are all aspects of the invention limited to use with fully depleted transistors. Still further, where a transistor has more than one parallel-connected fin passing under a common gate, all the fins for the transistor can be given the same underlap distance, or different fins can be given different underlap distances.

Additionally, without limitation, any and all variations described, suggested or incorporated by reference in the Background section of this patent application are specifically incorporated by reference into the description herein of embodiments of the invention. The embodiments described herein were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. An integrated circuit device having a substrate carrying a plurality of transistors including a first subset of at least one transistor and a second subset of at least one transistor,
wherein all of the transistors in the plurality are of a first conductivity type and have a channel region longitudinally separating source and drain regions,
and wherein the channel regions in all of the transistors in the first subset have the same first source underlap distance and the channel regions in all of the transistors in the second subset have the same second source underlap distance,
wherein the first and second source underlap distances are different.

2. A device according to claim 1, wherein all of the transistors in the first subset have the same first V_{T} and all of the transistors in the second subset have the same second V_{T},
and wherein the first and second V_{T} are different.

3. A device according to claim 1, wherein all of the transistors in the first subset have larger I_{eff} current and larger I_{off} current than all of the transistors in the second subset.

4. A device according to claim 1, wherein the plurality of transistors further includes a third subset of at least one transistor,
wherein the channel regions in all of the transistors in the third subset have the same third source underlap distance,
and wherein the third source underlap distance is different from both the first and second source underlap distances.

5. A device according to claim 1, wherein the channel regions in all of the transistors in the first and second subsets have the same drain underlap distances as their respective source underlap distances.

6. A device according to claim 1, wherein the channel regions in all of the transistors in at least the first subset of transistors are fully depleted.

7. A device according to claim 1, wherein the channel regions in all of the transistors in at least the first subset of transistors are partially depleted.

8. A device according to claim 1, wherein all of the transistors in the plurality are SOI transistors.

9. A device according to claim 1, wherein all of the transistors in the plurality are members of the group consisting of FinFETs, double-gate transistors, and triple-gate transistors.

10. A method for fabricating an integrated circuit device, comprising the steps of:
providing a wafer carrying a plurality of partial gate stacks for a plurality of transistors, the partial gate stacks including a first layer of material for gate dielectrics and a second layer of material for gate conductors superposing the first layer of material, the plurality of transistors being all of a first conductivity type and including a first subset of at least one transistor and a second subset of at least one transistor; and
forming source and drain diffusions for each of the transistors in the plurality, such that channel regions in all of the transistors in the first subset have the same first source underlap distance and channel regions in all of the transistors in the second subset have the same second source underlap distance,
wherein the first and second source underlap distances are different.

11. A method according to claim 10, wherein all of the transistors in the first subset have the same first V_{T} and all of the transistors in the second subset have the same second V_{T},
and wherein the first and second V_{T} are different.

12. A method according to claim 10, wherein all of the transistors in the first subset have larger I_{eff} current and larger I_{off} current than all of the transistors in the second subset.

13. A method according to claim 10, wherein the plurality of transistors further includes a third subset of at least one transistor,
wherein the channel regions in all of the transistors in the third subset have the same third source underlap distance,
and wherein the third source underlap distance is different from both the first and second source underlap distances.

14. A method according to claim 10, wherein the step of forming comprises the steps of:
forming sidewall spacers of a first thickness on the partial gate stacks of the transistors in the first subset;
forming sidewall spacers of a second thickness different from the first thickness on the partial gate stacks of the transistors in the second subset; and
doping the source and drain regions of all the transistors in the plurality using a processing method that diffuses dopant atoms longitudinally under the spacers from the source and drain regions.

15. A method according to claim 14, wherein the processing method comprises epitaxy with in-situ doping.

16. A method according to claim 10, wherein the step of forming comprises the steps of:
forming sidewall spacers on the partial gate stacks of all the transistors in the plurality;
doping the source and drain regions of the transistors in the first subset using a first dopant; and
doping the source and drain regions of the transistors in the second subset using a second dopant,
wherein the first and second dopants diffuse under the spacers at different rates.

17. A method according to claim 10, wherein the step of forming comprises the steps of:
forming sidewall spacers on the partial gate stacks of all the transistors in the plurality;
implanting dopant atoms into the source and drain regions of the transistors in the first subset using a first tilt angle; and
implanting dopant atoms into the source and drain regions of the transistors in the second subset using a second tilt angle,
wherein the first and second tilt angles are different.

18. A method according to claim 10, wherein the step of forming comprises the steps of:
forming sidewall spacers on the partial gate stacks of all the transistors in the plurality;
doping the source and drain regions of the transistors in the first subset;
annealing the device a first time such that dopant atoms in the source and drain regions of the transistors in the first subset diffuse under the spacers of transistors in the first subset to respective first distances longitudinally;
doping the source and drain regions of the transistors in the second subset; and
annealing the device a second time such that dopant atoms in the source and drain regions of the transistors in the second subset diffuse under the spacers of transistors in the second subset to respective second distances longitudinally, and such that dopant atoms in the source and drain regions of the transistors in the first subset diffuse further under the spacers of transistors in the first subset to respective third distances longitudinally, all of the third distances being greater than all of the second distances.
